(19) United States
(12) Patent Application Publication
(10) Pub. No.: US 2026/0090241 A1
(43) Pub. Date: Mar. 26, 2026

(54) DISPLAY DEVICE, METHOD OF MANUFACTURING THE SAME, AND ELECTRONIC DEVICE INCLUDING THE SAME

(71) Applicant: SAMSUNG DISPLAY CO., LTD., YONGIN-SI (KR)

(72) Inventor: JONGHWAN CHO, Yongin-si (KR)

(21) Appl. No.: 19/233,013

(22) Filed: Jun. 10, 2025

(30) Foreign Application Priority Data
Sep. 26, 2024 (KR) 10-2024-0130628

(51) Int. Cl. H10K 59/80; H10K 59/12; H10K 102/00

(52) U.S. Cl. CPC H10K 59/873; H10K 59/1201; H10K 2102/351

(57) ABSTRACT

A display device includes a display panel that displays an image. A window layer is arranged on the display panel. A protective film is arranged on the window layer. The protective film includes a base layer directly contacting the window layer. A hard coating layer is arranged on the base layer. A first functional layer is arranged on the hard coating layer and includes a metal alkoxide compound. A second functional layer is arranged on the first functional layer and includes a cross-linking structure of a fluorinated acrylate compound.

### CROSS-REFERENCE TO RELATED APPLICATION

This application claims priority under 35 U.S.C. § 119 to Korean Patent Application No. 10-2024-0130628, filed on Sep. 26, 2024 in the Korean Intellectual Property Office, the disclosure of which is incorporated by reference in its entirety herein.

### 1. TECHNICAL FIELD

The present disclosure relates generally to a display device. More particularly, the present disclosure relates to a display device, a method of manufacturing the same, and an electronic device including the same.

### 2. DISCUSSION OF RELATED ART

A display device is an electronic device that displays images to a user and serves as a connection medium between a user and information. Display devices have become increasingly important along with the development of the information society. For example, the use of display devices such as liquid crystal display (LCD) device, organic light emitting diode (OLED) display device, plasma display panel (PDP) device, quantum dot display device or the like is increasing.

A foldable display (e.g., a flexible display) may include a protective film covering a window of the display device. The protective film should be flexible to prevent cracks from occurring even when folding or bending the display device. In addition, research is being conducted to reduce the reflection of external light by the foldable display (e.g., flexible display) for increased image quality to the user.

### SUMMARY

Embodiments provide a display device with increased display quality.

Embodiments provide a method of manufacturing the display device.

Embodiments provide an electronic device including the display device.

According to an embodiment of the present disclosure, a display device includes a display panel that displays an image. A window layer is arranged on the display panel. A protective film is arranged on the window layer. The protective film includes a base layer directly contacting the window layer. A hard coating layer is arranged on the base layer. A first functional layer is arranged on the hard coating layer and includes a metal alkoxide compound. A second functional layer is arranged on the first functional layer and includes a cross-linking structure of a fluorinated acrylate compound.

In an embodiment, the metal alkoxide compound may include a titanium.

In an embodiment, the metal alkoxide compound may include a tetrabutyl orthotitanate tetramer represented by Formula 1-1 or a tetrakis(2-ethylhexyl) orthotitanate represented by Formula 1-2.

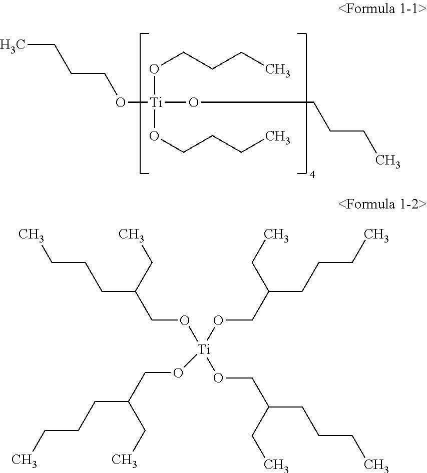

In an embodiment, a thickness of the first functional layer may be in a range of about 90 nanometers to about 150 nanometers.

In an embodiment, the second functional layer may include a polymer derived from a dodecafluoroheptyl acrylate.

In an embodiment, the second functional layer may include a cross-linking structure of a fluorinated acrylate compound comprising a repeating unit of Formula 2 below.

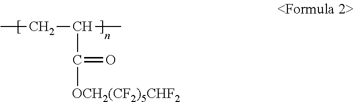

n may be any one of 6, 8, 10, and 12.

In an embodiment, the second functional layer may further include a cross-linking agent, and the cross-linking agent may include an acrylamide group or a vinyl group.

In an embodiment, a thickness of the second functional layer may be in a range of about 90 nanometers to about 110 nanometers.

In an embodiment, a first refractive index of the first functional layer may be greater than a second refractive index of the second functional layer.

In an embodiment, the protective film may have a reflectance of less than or equal to about 1%.

In an embodiment, the protective film may have an elastic strain in a range of about 7% to about 25%.

In an embodiment, a radius of curvature of the protective film may be less than or equal to about 2 millimeters.

According to an embodiment of the present disclosure, a method of manufacturing a display device includes forming a hard coating layer on a base layer. A first functional layer including a metal alkoxide compound is formed on the hard coating layer. A second functional layer including a cross-linking structure of a fluorinated acrylate compound is formed on the first functional layer. A window layer and the base layer are bonded to each other. The window layer and the base layer directly contact each other. The window layer is arranged on a display panel that displays an image.

In an embodiment, the first functional layer may be formed by a method of slit coating, spin coating, or inkjet printing.

In an embodiment, the metal alkoxide compound may include a titanium.

In an embodiment, the second functional layer may be formed by a vacuum deposition polymerization process.

In an embodiment, the forming of the second functional layer may include loading the base layer, the hard coating layer, and the first functional layer on a supporting part arranged inside a vacuum chamber, supplying the fluorinated acrylate compound and an inert gas to an interior of the vacuum chamber, ionizing and accelerating the inert gas, and forming the second functional layer on the first functional layer by colliding the fluorinated acrylate compound and the inert gas with each other.

In an embodiment, the second functional layer may include a polymer derived from a dodecafluoroheptyl acrylate.

In an embodiment, the second functional layer may include a cross-linking structure of a fluorinated acrylate compound comprising a repeating unit of Formula 2 below.

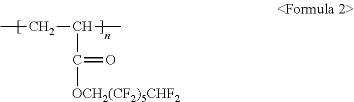

n may be any one of 6, 8, 10, and 12.

According to an embodiment, an electronic device according to an embodiment of the present disclosure includes a display panel that displays an image. A processor transmits an image data signal and an input control signal to the display panel. A window layer is arranged on the display panel. A protective film is arranged on the window layer. The protective film includes: a base layer directly contacting the window layer. A hard coating layer is arranged on the base layer. A first functional layer is arranged on the hard coating layer and includes a metal alkoxide compound. A second functional layer is arranged on the first functional layer and includes a cross-linking structure of a fluorinated acrylate compound.

A display device according to an embodiment of the present disclosure may include a display panel which displays an image, a window layer arranged on the display panel, and a protective film arranged on the window layer. The protective film may include a hard coating layer arranged on a base layer, a first functional layer arranged on the hard coating layer and including a metal alkoxide compound, and a second functional layer arranged on the first functional layer and including a cross-linking structure of a fluorinated acrylate compound.

The first functional layer may strengthen the adhesion between the hard coating layer and the second functional layer. The second functional layer, together with the first functional layer, may reduce the reflectance of the display device. Accordingly, the visibility of the display device may be increased.

Each of the first functional layer and the second functional layer may have a single-layer structure. Accordingly, the protective film may have a relatively high elastic strain, and cracks in the protective film may be prevented during folding and unfolding operations of the display device.

### BRIEF DESCRIPTION OF THE DRAWINGS

Illustrative, non-limiting embodiments will be more clearly understood from the following detailed description in conjunction with the accompanying drawings.

FIG. 1 is a perspective view illustrating an unfolded shape of a display device according to an embodiment of the present disclosure.

FIGS. 2 and 3 are perspective views illustrating a folded shape of the display device of FIG. 1 according to embodiments of the present disclosure.

FIG. 4 is an exploded perspective view illustrating the display device of FIG. 1 according to an embodiment of the present disclosure.

FIG. 5 is a cross-sectional view illustrating the display device of FIG. 1 according to an embodiment of the present disclosure.

FIGS. 6, 7, 8, 9, 10, and 11 are cross-sectional views illustrating a method of manufacturing a display device according to embodiments of the present disclosure.

FIG. 12 is a block diagram of an electronic device according to an embodiment of the present disclosure.

FIG. 13 is a schematic diagram of an electronic device according to various embodiments of the present disclosure.

### DETAILED DESCRIPTION OF EMBODIMENTS

Hereinafter, embodiments of the present disclosure will be described in detail with reference to the accompanying drawings. The same reference numerals are used for the same components in the drawings, and redundant descriptions of the same components will be omitted.

The present disclosure concerns a display device that includes a protective layer disposed directly on a window layer. The protective film includes a first functional layer disposed on a hard coating layer. The first functional layer comprises a metal alkoxide compound. A second functional layer is disposed on the first functional layer. The second functional layer comprises a cross-linking structure of a fluorinated acrylate compound. The first and second functional layers may each have a single-layer structure. The first functional layer strengthens adhesion between the hard coating layer and the second functional layer.

The refractive index of the first functional layer may be greater than the refractive index of the second functional layer. The first and second functional layers may provide a reflectance for the protective film that is less than or equal to about 1%. Therefore, the visibility of the display device and the quality of the images displayed by the display device may be increased.

The elastic strain of the protective film may be in a range of about 7% to about 25%. Therefore, cracks may be prevented from being formed during folding and unfolding of the display device.

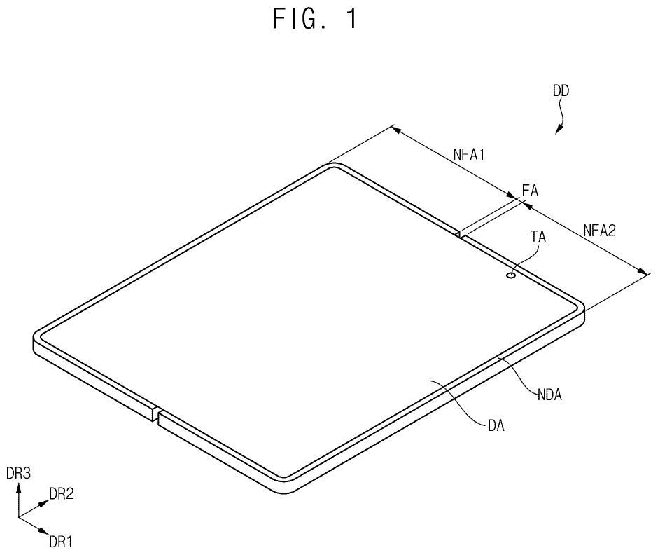

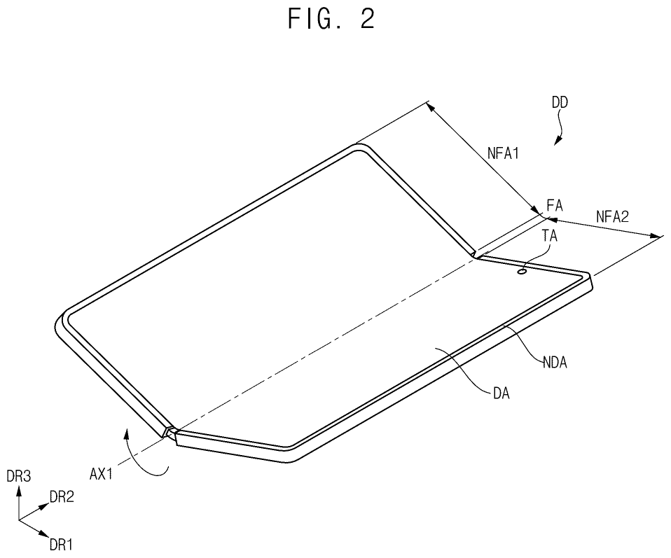

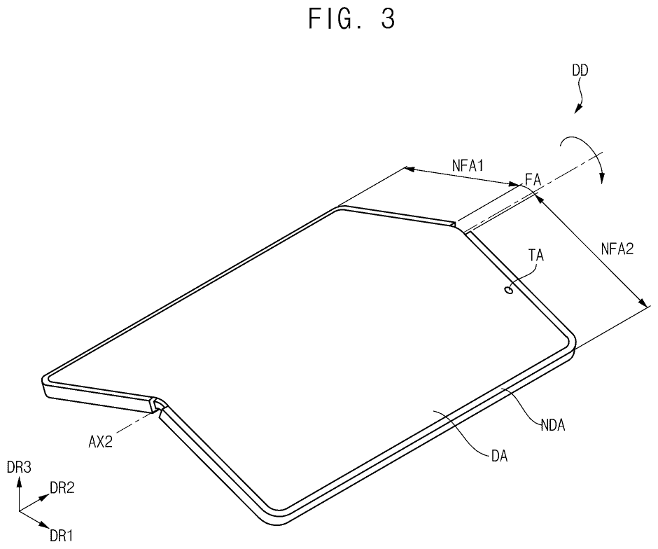

FIG. 1 is a perspective view illustrating an unfolded shape of a display device according to an embodiment of the present disclosure. FIGS. 2 and 3 are perspective views illustrating a folded shape of the display device of FIG. 1. For example, FIG. 2 is a perspective view illustrating an in-folded shape of the display device of FIG. 1. For example, FIG. 3 is a perspective view illustrating an out-folded shape of the display device of FIG. 1.

In this specification, a plane may be defined by a first direction DR1 and a second direction DR2 intersecting the first direction DR1. For example, in an embodiment the first direction DR1 and the second direction DR2 may be perpendicular to each other. A direction normal to the plane, that is, a thickness direction of a display device DD may be a third direction DR3. For example, the third direction DR3 may be perpendicular to each of the first direction DR1 and the second direction DR2. However, embodiments of the present disclosure are not necessarily limited thereto and the first to third directions DR1 to DR3 my cross each other at various different angles.

Referring to FIGS. 1, 2, and 3, the display device DD according to an embodiment of the present disclosure may include a display area DA, a transmission area TA, and a non-display area NDA.

The display area DA may be defined as an area that displays an image by generating light or adjusting the transmittance of light provided from an external light source. A plurality of pixels may be arranged in the display area DA. Each of the pixels may generate light in response to a driving signal. For example, in an embodiment the pixels may be arranged in a matrix form along the first direction DR1 and the second direction DR2. An upper surface of the display device DD may be defined as a display surface, and the display surface may have the plane defined by the first direction DR1 and the second surface DR2. An image generated by the display device DD may be provided to a user through the display surface.

The non-display area NDA may be positioned around the display area DA (e.g., in the first and/or second directions DR1, DR2). The non-display area NDA may surround at least a portion of the display area DA in a plan view. For example, the non-display area NDA may entirely surround the display area DA in a plan view. The non-display area NDA may be defined as an area that does not display an image. A scan driver, a data driver, or the like that provide the driving signal to the pixels may be arranged in the non-display area NDA.

The transmission area TA may have a transmittance higher than a transmittance of the display area DA and a transmittance of the non-display area NDA. Natural light, visible light, infrared light, or the like may travel into an interior of the display device DD through the transmission area TA. In an embodiment, the display device DD may further include a sensor that captures an external image using visible light passing through the transmission area TA or determines the approach of an external object using infrared rays passing through the transmission area TA. The sensor may overlap the transmission area TA in a plan view. For example, the transmission area TA may be positioned inside the display area DA. However, the embodiments of the present disclosure are not necessarily limited thereto, and the transmission area TA may be positioned inside the non-display area NDA, or may be surrounded by the display area DA and the non-display area NDA.

As illustrated in FIG. 2, the display device DD may be a foldable display device. For example, in an embodiment the display device DD may be foldable along a first folding axis AX1 that is imaginary and extends in the second direction DR2.

In an embodiment, the display device DD may include a folding area FA folded by the first folding axis AX1 and a first non-folding area NFA1 and a second non-folding area NFA2 that are spaced apart from each other in the first direction DR1 by the folding area FA.

In an embodiment, the display device DD may be folded in an in-folding manner with respect to the first folding axis AX1. Here, the in-folding manner may refer to a manner in which the first non-folding area NFA1 and the second non-folding area NFA2 are folded in a direction facing each other so that the display surface is not exposed to the outside (e.g., the external environment). However, embodiments of the present disclosure are not necessarily limited thereto and the display device DD may be folded in various other manners.

For example, in an embodiment as illustrated in FIG. 3, the display device DD may be folded along a second folding axis AX2 that is imaginary and extends in the second direction DR2. In this embodiment, the display device DD may be folded in an out-folding manner with respect to the second folding axis AX2. Here, the out-folding manner may refer to a manner in which the first non-folding area NFA1 and the second non-folding area NFA2 are folded in a direction opposite to each other so that the display surface is exposed to the outside (e.g., the external environment).

For example, the display device DD may be operated in only one manner selected from the in-folding manner and the out-folding manner. However, embodiments of the present disclosure are not necessarily limited thereto, and the display device DD may be operated in the in-folding method or the out-folding method with respect to one folding axis.

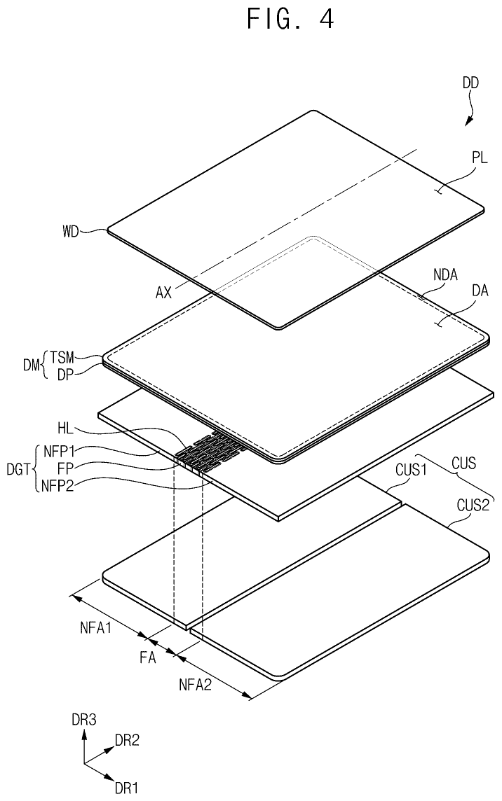

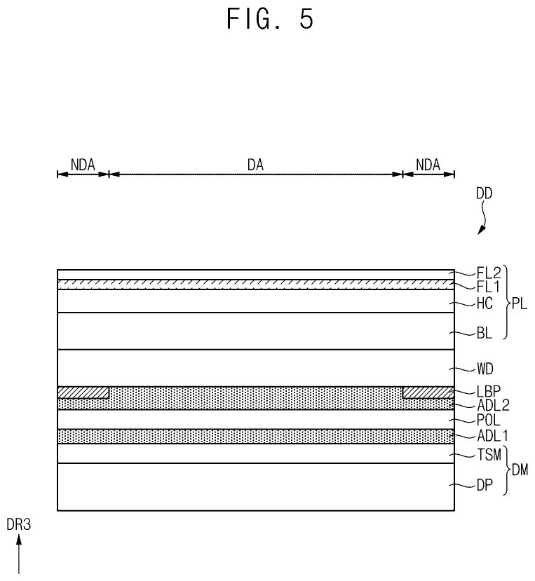

FIG. 4 is an exploded perspective view illustrating the display device of FIG. 1. FIG. 5 is a cross-sectional view illustrating the display device of FIG. 1. For convenience of description, FIG. 5 illustrates only a display module DM and upper functional layers arranged on the display module DM.

Referring to FIGS. 4 and 5, in an embodiment the display device DD may include the display module DM, the upper functional layers arranged on the display module DM, and lower functional layers arranged under the display module DM. In an embodiment the upper functional layers may include a polarization layer POL, a window layer WD, and a protective film PL. The lower functional layers may include a digitizer DGT and a cushioning layer CUS.

The display module DM may include a display panel DP and a touch member TSM. The display panel DP may display an image. The display panel DP may include a plurality of light-emitting elements that emit light. Each of the light-emitting elements may include a lower electrode, a light-emitting layer, and an upper electrode. A hole provided in the lower electrode and an electron provided in the upper electrode may combine to form an exciton in the light-emitting layer, and the light-emitting layer may emit light when the exciton changes from an excited state to a ground state. The light-emitting layer may emit light having a specific color. For example, in an embodiment the light-emitting layer may emit light have the color of red, green, blue, etc. For example, in an embodiment the light-emitting layer may include at least one of an organic light-emitting material and a quantum dot.

The touch member TSM may be arranged on the display panel DP. For example, in an embodiment the touch member TSM may be arranged directly on the display panel DP. For example, the touch member TSM may be arranged directly on the display panel DP (e.g., in the third direction DR3) without an adhesive member. However, embodiments of the present disclosure are not necessarily limited thereto, and the touch member TSM may be attached to an upper surface of the display panel DP through an adhesive member.

The touch member TSM may detect a user's touch. For example, the touch member TSM may acquire coordinate information according to an external input such as a user's touch. For example, the touch member TSM may acquire the coordinate information according to the external input using a mutual capacitance method and/or a self-capacitance method. The touch member TSM may include a plurality of touch electrodes, routing lines connected to the corresponding touch electrodes, and at least one touch insulating layer.

The digitizer DGT may be arranged under the display module DM (e.g., in a direction opposite to the third direction DR3). For example, the digitizer DGT may be arranged under the display panel DP (e.g., directly thereunder in the direction opposite to the third direction DR3). In an embodiment, the digitizer DGT may detect an input by an electromagnetic pen. For example, the digitizer DGT may be driven by electromagnetic resonance (EMR) using electromagnetic induction. The digitizer DGT may include a first non-folding portion NFP1, a second non-folding portion NFP2, and a folding portion FP.

The first non-folding portion NFP1 may at least partially overlap the first non-folding area NFA1. The second non-folding portion NFP2 may at least partially overlap the second non-folding area NFA2. The folding portion FP may overlap the folding area FA. The folding portion FP may be arranged between the first non-folding portion NFP1 and the second non-folding portion NFP2 (e.g., in the first direction DR1). A plurality of through holes HL may be defined in the folding portion FP. The through holes HL may penetrate the folding portion FP in a thickness direction (e.g., third direction DR3). The through holes HL may be spaced apart from each other in the first direction DR1 and/or the second direction DR2.

The cushioning layer CUS may be arranged under the digitizer DGT. The cushioning layer CUS may protect the display module DM from external impact. In addition, the cushioning layer CUS may prevent foreign substances from entering the through holes HL when the display device DD is unfolded. For example, in an embodiment the cushioning layer CUS may include a foam tape or a foam pad.

In an embodiment, the cushioning layer CUS may include a first cushioning layer CUS1 and a second cushioning layer CUS2. The first cushioning layer CUS1 may be spaced apart from the second cushioning layer CUS2 in the first direction DR1 within the folding area FA. The first cushion layer CUS1 may overlap the first non-folding portion NFP1 and a portion of the folding portion FP in a plan view. The second cushioning layer CUS2 may overlap the second non-folding portion NFP2 and another portion of the folding portion FP in a plan view. As the first cushioning layer CUS1 is spaced apart from the second cushioning layer CUS2 within the folding area FA, the shape of the digitizer DGT may be easily deformed when the folding portion FP is folded with a curvature (e.g., a predetermined curvature).

As illustrated in FIG. 5, the polarization layer POL may be arranged on the display module DM. For example, the polarization layer POL may be arranged on the touch member TSM. For example, in an embodiment the polarization layer POL may be attached to an upper surface of the touch member TSM through a first adhesive layer ADL1. The polarization layer POL may reduce the external light reflection of the display device DD. For example, the polarization layer POL may include a polarizer and/or a phase retarder.

The first adhesive layer ADL1 may be arranged between the display module DM and the polarization layer POL (e.g., in the third direction DR3). The first adhesive layer ADL1 may attach the display module DM and the polarization layer POL to each other.

The window layer WD may be arranged on the polarization layer POL. The window layer WD may cover and protect the display module DM and the polarization layer POL. For example, in an embodiment the window layer WD may be attached to an upper surface of the polarization layer POL through a second adhesive layer ADL2. The window layer WD may include a transparent material to allow light provided by the display panel DP to pass through to the outside (e.g., the external environment). For example, the window layer WD may include glass or plastic. In an embodiment, the window layer WD may be an ultra-thin glass having a thickness less than or equal to about 0.3 millimeters or a transparent polyimide film. However, embodiments of the present disclosure are not necessarily limited thereto.

The second adhesive layer ADL2 may be arranged between the polarization layer POL and the window layer WD (e.g., in the third direction DR3). The second adhesive layer ADL2 may attach the polarization layer POL and the window layer WD to each other.

In an embodiment, each of the first adhesive layer ADL1 and the second adhesive layer ADL2 may include a pressure sensitive adhesive (PSA) film, an optically clear adhesive (OCA) film, or an optically clear resin (OCR). In an embodiment, each of the first adhesive layer ADL1 and the second adhesive layer ADL2 may include an optically clear resin.

In an embodiment, a light blocking layer LBP may be arranged at an edge portion of the window layer WD. The light blocking layer LBP may overlap the non-display area NDA. The light blocking layer LBP may prevent the driver or the like driving the display panel DP from being visible from the outside (e.g. the external environment). The light blocking layer LBP may include an inorganic material or an organic material including a light blocking material having a black color. For example, in an embodiment the light blocking layer LBP may include a black pigment, a black dye, carbon black, or the like. These materials may be used alone or in combination with each other.

The protective film PL may be arranged on the window layer WD (e.g., disposed directly thereon in the third direction DR3). In an embodiment, the protective film PL may include a base layer BL, a hard coating layer HC, a first functional layer FL1, and a second functional layer FL2.

The base layer BL may be arranged on the window layer WD (e.g., disposed directly thereon in the third direction DR3). The base layer BL may include an organic material. In an embodiment, the organic material that may be used as the base layer BL may include polyethylene terephthalate (PET), polyimide (PI), polyethylene naphthalate (PEN), polycarbonate (PC), polymethyl methacrylate (PMMA), or the like. These materials may be used alone or in combination with each other.

For example, in an embodiment a thickness (e.g., a length in the third direction DR3) of the base layer BL may be in range of about 30 micrometers to about 150 micrometers. For example, the thickness of the base layer BL may be in a range of about 50 micrometers to about 100 micrometers. However, embodiments of the present disclosure are not necessarily limited thereto.

The hard coating layer HC may be arranged on the base layer BL (e.g., disposed directly thereon in the third direction DR3). The hard coating layer HC may protect a surface of the window layer WD, and may increase the mechanical properties of the window layer WD. The hard coating layer HC may include an organic material. In an embodiment, the organic material that may be used as the hard coating layer HC may include polyimide (PI), polyethylene naphthalate (PEN), polycarbonate (PC), polymethyl methacrylate (PMMA), liquid crystal polymer, polyphenylene sulfide (PPS), or the like. These materials may be used alone or in combination with each other. For example, in an embodiment a thickness of the hard coating layer HC (e.g., length in the third direction DR3) may be in a range of about 3 micrometers to about 10 micrometers. However, embodiments of the present disclosure are not necessarily limited thereto.

The first functional layer FL1 may be arranged on the hard coating layer HC (e.g., disposed directly thereon in the third direction DR3). The first functional layer FL1 may strengthen the adhesion between the hard coating layer HC and the second functional layer FL2 described below. In an embodiment, the first functional layer FL1 may include a metal alkoxide compound. In an embodiment, the metal alkoxide compound may include titanium (Ti). For example, in an embodiment the metal alkoxide compound may include a titanium alkoxide oligomer, and the titanium alkoxide oligomer may include tetrabutyl orthotitanate tetramer represented by Formula 1-1 below or tetrakis(2-ethylhexyl) orthotitanate represented by Formula 1-2 below.

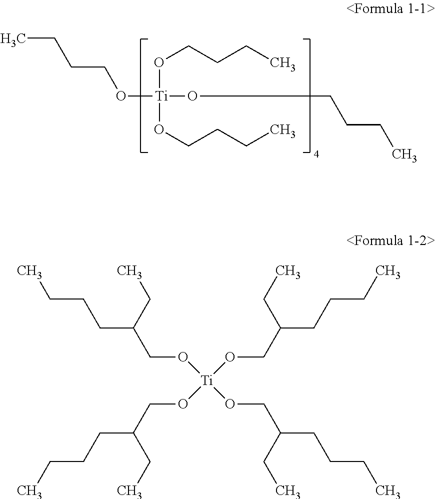

In an embodiment, the first functional layer FL1 may be formed by applying a metal alkoxide oligomer on the hard coating layer HC by a method such as slit coating, spin coating, inkjet printing, or the like.

In an embodiment, a thickness of the first functional layer FL1 (e.g., length in the third direction DR3) may be in a range of about 90 nanometers to about 150 nanometers. For example, the thickness of the first functional layer FL1 may be in a range of about 95 nanometers to about 130 nanometers.

The second functional layer FL2 may be arranged on the first functional layer FL1 (e.g., disposed directly thereon in the third direction DR3). In an embodiment, the second functional layer FL2 may include a cross-linked structure of a fluorinated acrylate compound. In an embodiment, the second functional layer FL2 may include a polymer derived from dodecafluoroheptyl acrylate (DFHA). For example, in an embodiment the second functional layer FL2 may include a cross-linked structure of a fluorinated acrylate compound including a repeating unit of Formula 2 below. For example, the second functional layer FL2 may be formed by cross-linking fluorinated acrylate compounds represented by Formula 2 below.

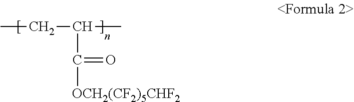

In the Formula 2, n may be any one of 6, 8, 10, and 12. For example, n may be any one of 8, 10, and 12. For example, n may be 8.

In an embodiment, the second functional layer FL2 may further include a cross-linking agent. The cross-linking agent may include an acrylamide group or a vinyl group.

In an embodiment, the cross-linking agent including the acrylamide group may be piperazine diacrylamide, N,N′-ethylenebisacrylamide, N,N′-methylenebisacrylamide, N,N′-methylenebismethacrylamide, N,N′,N″-triacryloyldiethylene triamine, N,N′-hexamethylenebis(methacrylamide)), or the like. In an embodiment, the cross-linking agent may include N,N′,N″-triacryloyldiethylene triamine represented by Formula 3-1 below. However, embodiments of the present disclosure are not necessarily limited thereto.

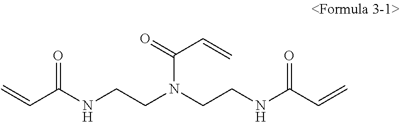 [SMILES: C=CC(=O)NCCN(CCNC(=O)C=C)C(=O)C=C]

In an embodiment, the cross-linking agent including the vinyl group may include diallyl adipate, triallyl isocyanurate, triallyl trimellitate, triallyl citrate, or the like. In an embodiment, the cross-linking agent may include triallyl trimellitate represented by Formula 3-2 below. However, embodiments of the present disclosure are not necessarily limited thereto.

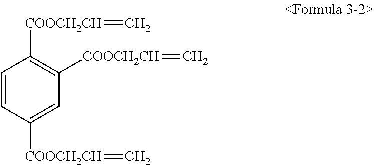

In an embodiment, a thickness of the second functional layer FL2 (e.g., length in the third direction DR3) may be in a range of about 90 nanometers to about 110 nanometers. For example, the thickness of the second functional layer FL2 may be in a range of about 95 nanometers to about 100 nanometers.

In an embodiment, a first refractive index of the first functional layer FL1 may be greater than a second refractive index of the second functional layer FL2. For example, the first refractive index of the first functional layer FL1 may be in a range of about 1.6 to about 1.9, and the second refractive index of the second functional layer FL2 may be in a range of about 1.3 to about 1.5. For example, the first functional layer FL1 may be referred to as a high refractive layer, and the second functional layer FL2 may be referred to as a low refractive layer. The second functional layer FL2 may reduce the reflectance of the display device DD together with the first functional layer FL1. Accordingly, the visibility of the display device DD may be increased. In an embodiment, the reflectance of the protective film PL may be less than or equal to about 1%, such as less than or equal to about 1% of the total external light directed on the protective film PL.

A functional layer such as an anti-fingerprint layer may not be arranged on the second functional layer FL2. For example, the second functional layer FL2 may have high resistance to external scratches even without a wear-resistant treatment such as the anti-fingerprint layer.

In an embodiment, each of the first functional layer FL1 and the second functional layer FL2 may have a single-layer structure. In this embodiment, compared to a low-reflection structure including at least four refractive layers in which a first refractive layer and a second refractive layer having different refractive indices are sequentially stacked to reduce the reflectance of the display device DD, the protective film PL may have a relatively high elastic strain (e.g., crack strain). In an embodiment, the elastic strain of the protective film PL may be in a range of about 7% to about 25%. In a comparative embodiment in which the elastic strain of the protective film PL is less than about 7%, cracks may occur in the protective film PL during folding and unfolding operations of the display device DD.

In an embodiment, a radius of curvature of the protective film PL may be less than or equal to about 2 millimeters. For example, in an embodiment the radius of curvature of the protective film PL may be in a range of about 0.5 millimeters to about 2 millimeters. As the protective film PL has the radius of curvature, the foldable performance of the display device DD may be further increased.

Hereinafter, the effects of the present disclosure are described through specific embodiments and comparative examples.

### EMBODIMENT 1

A protective film PL, which includes a base layer (thickness: about 65 micrometers) including polyethylene terephthalate (PET), a hard coating layer (thickness: about 5 micrometers) arranged on the base layer, a first functional layer FL1 (thickness: about 97 nanometers) arranged on the hard coating layer and formed by applying tetrabutyl orthotitanate tetramer using a slit coating method, and a second functional layer FL2 (thickness: about 95 nanometers) arranged on the first functional layer FL1 and formed by polymerizing a dodecafluoroheptyl acrylate (DFHA) monomer and an N,N′,N″-triacryloyldiethylene triamine cross-linking agent, was formed. A refractive index of the first functional layer FL1 is about 1.63, and a refractive index of the second functional layer FL2 is about 1.342.

### EMBODIMENT 2

A protective film PL, which includes a base layer (thickness: about 65 micrometers) including polyethylene terephthalate (PET), a hard coating layer (thickness: about 5 micrometers) arranged on the base layer, a first functional layer FL1 (thickness: about 127 nanometers) arranged on the hard coating layer and formed by applying tetrakis(2-ethylhexyl) orthotitanate using a slit coating method, and a second functional layer FL2 (thickness: about 95 nanometers) arranged on the first functional layer FL1 and formed by polymerizing a dodecafluoroheptyl acrylate (DFHA) monomer and a triallyl trimellitate cross-linking agent, was formed. A refractive index of the first functional layer FL1 is about 1.81, and a refractive index of the second functional layer FL2 is about 1.342.

### COMPARATIVE EXAMPLE 1

A protective film, which includes a base layer (thickness: about 50 micrometers) including polyethylene terephthalate (PET), a hard coating layer (thickness: about 5 micrometers) arranged on the base layer, a first refractive layer (thickness: about 110 nanometers) arranged on the hard coating layer and including ZrO₂, and a second refractive layer (thickness: about 80 nanometers) arranged on the first refractive layer and including SiO, was formed.

### COMPARATIVE EXAMPLE 2

A protective film, which includes a base layer (thickness: about 50 micrometers) including polyethylene terephthalate (PET), a hard coating layer (thickness: about 5 micrometers) arranged on the base layer, a first refractive layer (thickness: about 11 nanometers) arranged on the hard coating layer and including Nb₂O₅, a second refractive layer (thickness: about 25 nanometers) arranged on the first refractive layer and including SiO₂, a third refractive layer (thickness: about 105 nanometers) arranged on the second refractive layer and including Nb₂O₅, and a fourth refractive layer (thickness: about 68 nanometers) arranged on the third refractive layer and including SiO₂, was formed.

### Experiments

The specular component included (SCI) reflectance and elastic strain were measured on protective films satisfying the Embodiment 1, the Embodiment 2, the Comparative Example 1, and the Comparative Example 2, and the results are shown in Table 1 below. The SCI reflectance was measured using a CM-3700A spectrophotometer from Konica Minolta. The elastic strain was measured as the increase in the size of the test sample after tension relative to the initial test sample. The test sample for measuring the elastic strain was prepared by laser cutting with a size of 1.0 cm×10 cm. The tensile speed was 10 mm/min.

As a result, referring to Table 1 below, the SCI reflectance of the protective film satisfying the Comparative Example 1 was measured to be about 1.33%. The elastic strain of the protective film satisfying the Comparative Example 1 was measured to be about 4.5%. The SCI reflectance of the protective film satisfying the Comparative Example 2 was measured to be about 0.25%. The elastic strain of the protective film satisfying the Comparative Example 2 was measured to be about 2.0%.

The SCI reflectance of the protective film PL satisfying the Embodiment 1 was measured to be about 0.22%. The elastic strain of the protective film PL satisfying the Embodiment 1 was measured to be about 7.4%. The SCI reflectance of the protective film PL satisfying the Embodiment 2 above was measured to be about 0.41%. The elastic strain of the protective film PL satisfying the Embodiment 2 was measured to be about 7.5%.

TABLE 1

| | Embodiment | Embodiment | Comparative | Comparative |
|---|---|---|---|---|
| | 1 | 2 | Example 1 | Example 2 |
| SCI reflectance | 0.22 | 0.41 | 1.33 | 0.25 |
| (%) | | | | |
| elastic strain | 7.4 | 7.5 | 4.5 | 2.0 |
| (%) | | | | |

As these results indicate, the protective films PL satisfying the Embodiment 1 and the Embodiment 2 may have the reflectance of less than or equal to about 1% and the elastic strain of greater than or equal to about 7%. For example, the protective films PL according to embodiments of the present disclosure may reduce the reflectance of the display device DD to increase the visibility of the display device DD and the quality of the images displayed by the display device DD, and may prevent cracks from occurring during folding and unfolding operations of the display device DD.

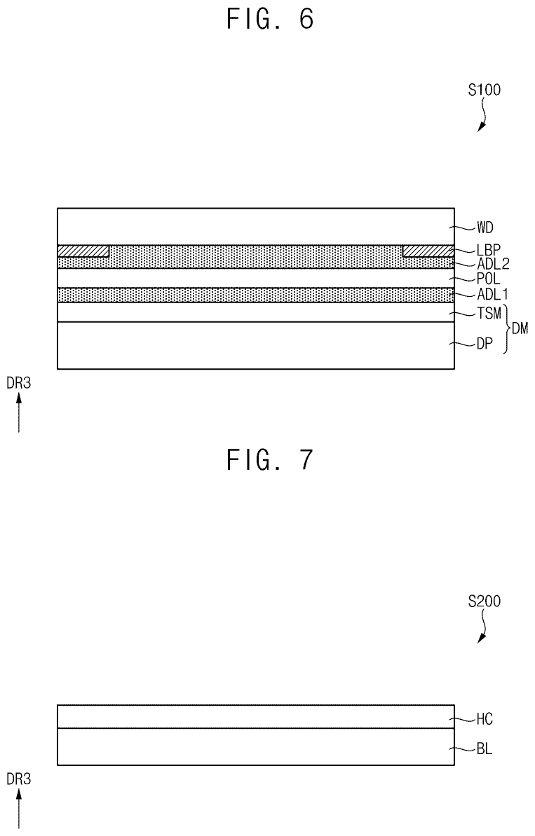

FIGS. 6, 7, 8, 9, 10, and 11 are cross-sectional views illustrating a method of manufacturing a display device according to embodiments of the present disclosure. For example, FIGS. 6 to 11 are cross-sectional views illustrating a method of manufacturing the display device DD described above with reference to FIGS. 1 to 5. A description of a method of manufacturing the digitizer (DGT, refer to FIG. 4) and the cushion layer (CUS, refer to FIG. 4) arranged under the display panel DP may be omitted for economy of explanation.

Referring to FIG. 6, the display panel DP and the window layer WD formed on the display panel DP may be provided in block S100.

The display panel DP may include a plurality of light-emitting elements that emit light. Accordingly, the display panel DP may display an image, such as at least one static and/or moving image. The touch member TSM may be arranged on the display panel DP (e.g., disposed directly thereon in the third direction DR3). The touch member TSM may detect a user's touch. The polarization layer POL may be arranged on the touch member TSM. For example, in an embodiment the polarization layer POL may be attached to an upper surface of the touch member TSM through the first adhesive layer ADL1. The polarization layer POL may reduce the external light reflection of the display device DD.

The window layer WD may be arranged on the display panel DP (e.g., in the third direction DR3). For example, the window layer WD may be arranged on the polarization layer POL. For example, in an embodiment the window layer WD may be attached to an upper surface of the polarization layer POL through the second adhesive layer ADL2. The window layer WD may cover and protect the display module DM and the polarization layer POL. In an embodiment, the light blocking layer LBP may be arranged on an edge portion of the window layer WD. The light blocking layer LBP may prevent the driver or the like elements driving the display panel DP from being visible from the outside (e.g., the external environment).

Referring to FIG. 7, the hard coating layer HC may be formed on (e.g., formed directly thereon in the third direction DR3) the base layer BL in block S200.

The base layer BL may include an organic material. In an embodiment, the organic material that may be used as the base layer BL may include polyethylene terephthal ate (PET), polyimide (PI), polyethylene naphthalate (PEN), polycarbonate (PC), polymethyl methacrylate (PMMA), or the like. These materials may be used alone or in combination with each other. In an embodiment, a thickness of the base layer BL (e.g., length in the third direction DR3) may be in a range of about 30 micrometers to about 150 micrometers. For example, the thickness of the base layer BL may be in a range of about 50 micrometers to about 100 micrometers.

The hard coating layer HC may be formed on the base layer BL. The hard coating layer HC may include an organic material. In an embodiment, the organic material that may be used as the hard coating layer HC may include polyimide (PI), polyethylene naphthalate (PEN), polycarbonate (PC), polymethyl methacrylate (PMMA), liquid crystal polymer, polyphenylene sulfide (PPS), or the like. These materials may be used alone or in combination with each other. For example, in an embodiment a thickness (e.g., length in the third direction DR3) of the hard coating layer HC may be in a range of about 3 micrometers to about 10 micrometers.

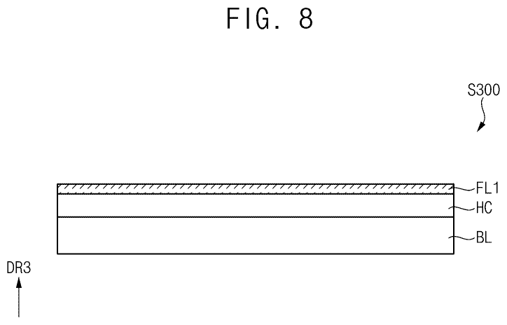

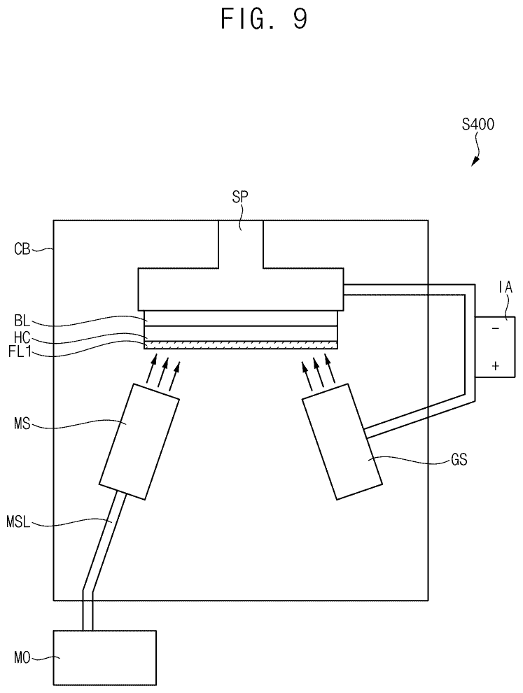

Referring to FIG. 8, the first functional layer FL1 may be formed on (e.g., formed directly thereon in the third direction DR3) the hard coating layer HC in block S300.

In an embodiment, the first functional layer FL1 may include a metal alkoxide compound. In an embodiment, the metal alkoxide compound may include titanium (Ti). For example, the metal alkoxide compound may include a titanium alkoxide oligomer, and the titanium alkoxide oligomer may include tetrabutyl orthotitanate tetramer or tetrakis(2-ethylhexyl) orthotitanate.

In an embodiment, the first functional layer FL1 may be formed by a method such as slit coating, spin coating, inkjet printing, or the like. For example, in an embodiment a composition including a metal alkoxide oligomer may be applied on (e.g., directly thereon) the hard coating layer HC by a method such as slit coating, spin coating, inkjet printing, or the like, and the composition may be dried to remove a solvent of the composition. Thereafter, the composition may be cured by irradiating light, such as ultraviolet light or the like, so that the first functional layer FL1 may be formed on the hard coating layer HC.

In an embodiment, a thickness of the first functional layer FL1 (e.g., length in the third direction DR3) may be in a range of about 90 nanometers to about 150 nanometers. For example, in an embodiment the thickness of the first functional layer FL1 may be in a range of about 95 nanometers to about 130 nanometers.

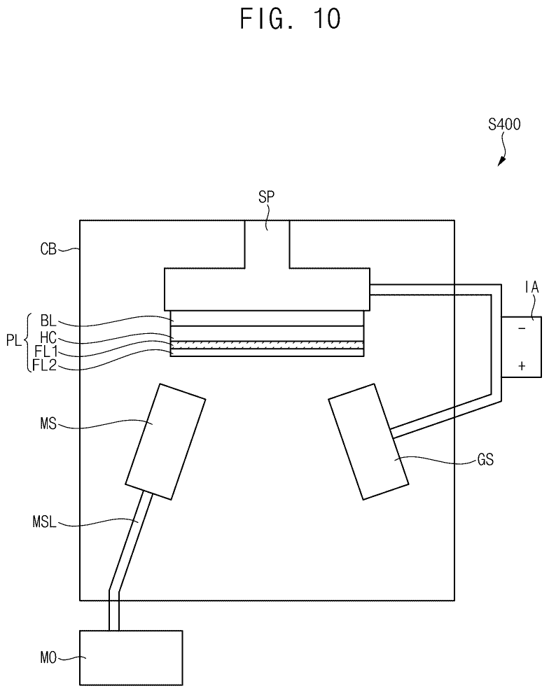

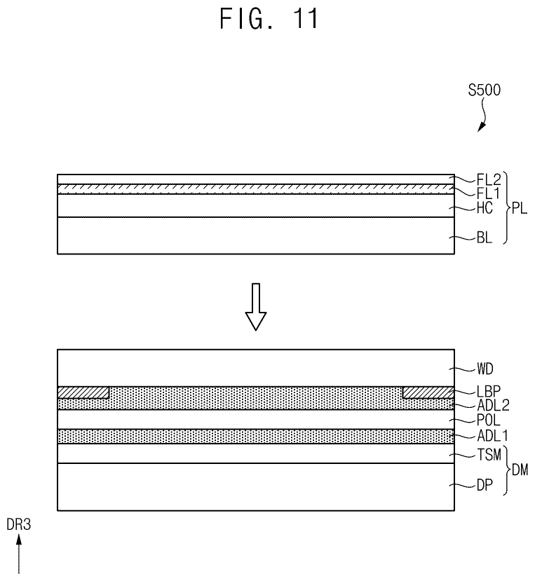

Referring to FIGS. 9 and 10, the second functional layer FL2 may be formed on the first functional layer FL1 (e.g., disposed directly thereon in the third direction DR3). In an embodiment, the second functional layer FL2 may be formed using a vacuum deposition apparatus.

In an embodiment, the vacuum deposition apparatus may include a chamber CB, a supporting part SP, an ion accelerator IA, a gas supply part GS, a monomer storage part MO, a monomer supply line MSL, and a monomer supply part MS.

The chamber CB may define a space in which a deposition process is performed. For example, the chamber CB may define a space in which a process of vacuum depositing the second functional layer FL2 on (e.g., directly thereon) the first functional layer FL1 is performed. The chamber CB may maintain in a vacuum state while the deposition process is performed.

The supporting part SP may be arranged inside the chamber CB. The supporting part SP may support the base layer BL, the hard coating layer HC, and the first functional layer FL1. For example, the base layer BL, the hard coating layer HC, and the first functional layer FL1 may be loaded onto the supporting part SP. For example, in an embodiment the supporting part SP may adsorb the base layer BL, the hard coating layer HC, and the first functional layer FL1 using electrostatic force. However, embodiments of the present disclosure are not necessarily limited thereto, and the supporting part SP may also support the base layer BL, the hard coating layer HC, and the first functional layer FL1 by a mechanical clamping method in some embodiments. Accordingly, the base layer BL, the hard coating layer HC, and the first functional layer FL1 may be sequentially stacked on the supporting part SP (e.g., in the third direction DR3).

The gas supply part GS may supply an inert gas to an interior of the chamber CB. For example, in an embodiment the inert gas may be helium gas (He), neon gas (Ne), argon gas (Ar), or the like. However, embodiments of the present disclosure are not necessarily limited thereto.

The ion accelerator IA may ionize and accelerate the inert gas provided inside the chamber CB. The ion accelerator IA may apply a bias voltage to the first functional layer FL1, and the inert gas may move toward the first functional layer FL1.

The monomer storage part MO, the monomer supply line MSL, and the monomer supply part MS may provide a monomer onto the first functional layer FL1. For example, the monomer stored in the monomer storage part MO may be provided inside the chamber CB through the monomer supply line MSL and the monomer supply part MS. In an embodiment, the monomer may include a fluorinated acrylate compound. In an embodiment, the monomer may include a fluorinated acrylate compound including a repeating unit of Formula 2 below.

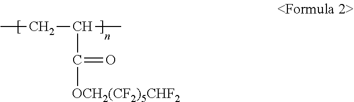

In the Formula 2, n may be any one of 6, 8, 10, and 12. For example, n may be any one of 8, 10, and 12. For example, n may be 8.

In an embodiment, the vacuum deposition apparatus may further include a cross-linking agent supply part that provides a cross-linking agent, and the cross-linking agent supply part may provide the cross-linking agent inside the chamber CB. In an embodiment, the cross-linking agent may include an acrylamide group or a vinyl group.

The fluorinated acrylate compounds may be cross-linked to each other on the first functional layer FL1. For example, in an embodiment the second functional layer FL2 may comprise a polymer derived from a dodecafluoroheptyl acrylate. The inert gas accelerated by the ion accelerator IA may collide with the fluorinated acrylate compounds on the first functional layer FL1. For example, the inert gas accelerated by the ion accelerator IA and the cross-linking agent may promote cross-linking of the fluorinated acrylate compounds. For example, the inert gas accelerated by the ion accelerator IA and the cross-linking agent may promote the vacuum deposition polymerization of the fluorinated acrylate compounds. The second functional layer FL2 may be formed on (e.g., formed directly thereon) the first functional layer FL1 by the cross-linking of the fluorinated acrylate compounds. Thus, the second functional layer FL2 may be formed by a vacuum deposition polymerization process. Accordingly, the second functional layer FL2 may include a cross-linking structure of the fluorinated acrylate compound.

In an embodiment, a thickness of the second functional layer FL2 (e.g., length in the third direction DR3) may be in a range of about 90 nanometers to about 110 nanometers. For example, in an embodiment the thickness of the second functional layer FL2 may be in a range of about 95 nanometers to about 100 nanometers.

Accordingly, the protective film PL in which the base layer BL, the hard coating layer HC, the first functional layer FL1, and the second functional layer FL2 are sequentially stacked may be formed. The protective film PL including the first functional layer FL1 and the second functional layer FL2 may have a reflectance of less than or equal to about 1% and an elastic strain of greater than or equal to about 7%.

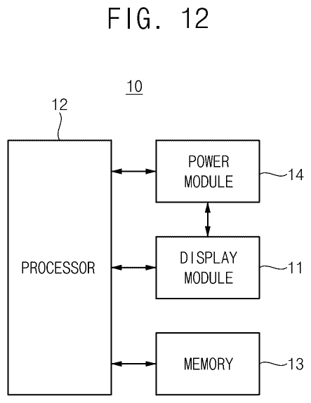

Referring to FIG. 11, the window layer WD and the base layer BL may be bonded to each other such that the window layer WD and the base layer BL directly contact each other in block S500. For example, the protective film PL may be attached to (e.g., attached directly thereto) the window layer WD. Accordingly, the display device DD illustrated in FIG. 5 may be manufactured.

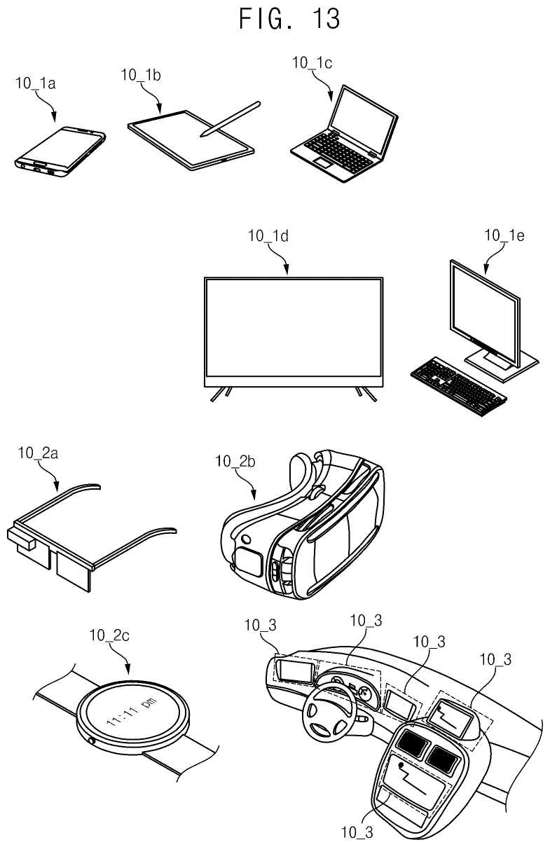

FIG. 12 is a block diagram of an electronic device according to an embodiment of the present disclosure.

Referring to FIG. 12, an electronic device 10 according to an embodiment may include a display module 11, a processor 12, a memory 13, and a power module 14. The display device according to an embodiment may be applied to a variety of electronic devices. The electronic device 10 according to an embodiment may include the display device described above, and may further include modules or devices having other additional functions in addition to the display device. In addition, the display module 11 may correspond to the display module DM of FIGS. 4 and 5. For example, the display module 11 may include the display panel DP of FIGS. 4 and 5.

In an embodiment, the processor 12 may include at least one of a central processing unit (CPU), an application processor (AP), a graphic processing unit (GPU), a communication processor (CP), an image signal processor (ISP), and a controller.

The memory 13 may store data information required for operation of the processor 12 or the display module 11. When the processor 12 executes an application stored in the memory 13, an image data signal and/or an input control signal may be transmitted to the display module 11, and the display module 11 may process the received signals and may output image information through a display screen.

In an embodiment, the power module 14 may include a power supply module, such as a power adapter or a battery device, etc., and a power conversion module that converts power supplied by the power supply module to generate the power required for operation of the electronic device 10. For example, the power module 14 may provide power to the display device according to embodiments described above.

At least one of the components of the electronic device 10 described above may be included in the display device according to embodiments described above. In addition, some of the individual modules that are functionally included in one module may be included in the display device and others may be provided separately from the display device. For example, in an embodiment the display device may include the display module 11, and the processor 12, the memory 13, and the power module 14 may be provided in the form of other devices in the electronic device 10 other than the display device.

FIG. 13 is a schematic diagram of an electronic device according to various embodiments.

Referring to FIG. 13, various electronic devices to which a display device according to embodiments of the present disclosure is applied may include image display electronic devices such as a smartphones 10_1a, a tablet PC 10_1b, a laptop 10_1c, a television 10_1d, a desk monitor 10_1e, or the like, wearable electronic devices including display modules such as a smart glasses 10_2a, a head-mounted display 10_2b, and a smart watch 10_2c, or the like, and vehicle electronic devices 10_3 including display modules such as a CID (center information display) which may be disposed on an instrument panel, a center fascia, and a dashboard of an automobile and a room mirror display, or the like.

The present disclosure may be applied to various display devices. For example, embodiments of the present disclosure is applicable to various display devices such as display devices for vehicles, ships and aircraft, portable communication devices, display devices for exhibition or information transmission, medical display devices, and the like. However, embodiments of the present disclosure are not necessarily limited thereto and the electronic device that the display device may be applied to may be various different small-sized, medium-sized or large-sized electronic devices.

The foregoing is illustrative of certain embodiments of the present disclosure, and is not to be construed as limiting thereof. Although a few non-limiting embodiments have been described with reference to the figures, those skilled in the art will readily appreciate that many variations and modifications may be made therein without departing from the spirit and scope of the present disclosure.

What is claimed is:

1. A display device comprising:
a display panel that displays an image;
a window layer arranged on the display panel; and
a protective film arranged on the window layer and comprising:
a base layer directly contacting the window layer;
a hard coating layer arranged on the base layer;
a first functional layer arranged on the hard coating layer and comprising a metal alkoxide compound; and
a second functional layer arranged on the first functional layer and comprising a cross-linking structure of a fluorinated acrylate compound.

2. The display device of claim 1, wherein the metal alkoxide compound comprises a titanium.

3. The display device of claim 2, wherein the metal alkoxide compound comprises a tetrabutyl orthotitanate tetramer represented by Formula 1-1 or a tetrakis(2-ethylhexyl) orthotitanate represented by Formula 1-2;

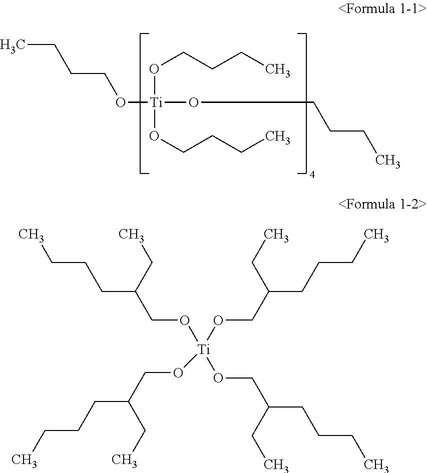

4. The display device of claim 1, wherein a thickness of the first functional layer is in a range of about 90 nanometers to about 150 nanometers.

5. The display device of claim 1, wherein the second functional layer comprises a polymer derived from a dodecafluoroheptyl acrylate.

6. The display device of claim 1, wherein the second functional layer comprises a cross-linking structure of a fluorinated acrylate compound comprising a repeating unit of Formula 2 below; 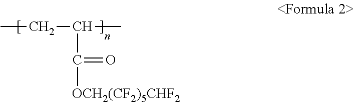
wherein n is any one of 6, 8, 10, and 12.

7. The display device of claim 1, wherein:
the second functional layer further comprises a cross-linking agent; and
the cross-linking agent comprises an acrylamide group or a vinyl group.

8. The display device of claim 1, wherein a thickness of the second functional layer is in a range of about 90 nanometers to about 110 nanometers.

9. The display device of claim 1, wherein a first refractive index of the first functional layer is greater than a second refractive index of the second functional layer.

10. The display device of claim 1, wherein the protective film has a reflectance of less than or equal to about 1%.

11. The display device of claim 1, wherein the protective film has an elastic strain in a range of about 7% to about 25%.

12. The display device of claim 1, wherein a radius of curvature of the protective film is less than or equal to about 2 millimeters.

13. A method of manufacturing a display device, the method comprising:
forming a hard coating layer on a base layer;
forming a first functional layer comprising a metal alkoxide compound on the hard coating layer;
forming a second functional layer comprising a cross-linking structure of a fluorinated acrylate compound on the first functional layer; and
bonding a window layer and the base layer to each other, wherein the window layer and the base layer directly contact each other, the window layer is arranged on a display panel that displays an image.

14. The method of claim 13, wherein the first functional layer is formed by a method of slit coating, spin coating, or inkjet printing.

15. The method of claim 13, wherein the metal alkoxide compound comprises a titanium.

16. The method of claim 13, wherein the second functional layer is formed by a vacuum deposition polymerization process.

17. The method of claim 16, wherein the forming of the second functional layer comprises:
loading the base layer, the hard coating layer, and the first functional layer on a supporting part arranged inside a vacuum chamber;
supplying the fluorinated acrylate compound and an inert gas to an interior of the vacuum chamber;
ionizing and accelerating the inert gas; and
forming the second functional layer on the first functional layer by colliding the fluorinated acrylate compound and the inert gas with each other.

18. The method of claim 13, wherein the second functional layer comprises a polymer derived from a dodecafluoroheptyl acrylate.

19. The method of claim 13, wherein the second functional layer comprises a cross-linking structure of a fluorinated acrylate compound comprising a repeating unit of Formula 2; 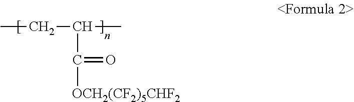
wherein n is any one of 6, 8, 10, and 12.

20. An electronic device comprising:
a display panel that displays an image;
a processor transmitting an image data signal and an input control signal to the display panel;
a window layer arranged on the display panel; and
a protective film arranged on the window layer,
wherein the protective film comprises:
a base layer directly contacting the window layer;
a hard coating layer arranged on the base layer;
a first functional layer arranged on the hard coating layer and comprising a metal alkoxide compound; and
a second functional layer arranged on the first functional layer and comprising a cross-linking structure of a fluorinated acrylate compound.
